(19) United States
(12) Patent Application Publication
(10) Pub. No.: US 2017/0352424 A1
(43) Pub. Date: Dec. 7, 2017

(54) Plural Distributed PBS with Both Voltage and Current Sensing SA for J-Page Hierarchical NAND Array's Concurrent Operations

(71) Applicant: Peter Wung Lee, Saratoga, CA (US)

(72) Inventor: Peter Wung Lee, Saratoga, CA (US)

(21) Appl. No.: 15/615,883

(22) Filed: Jun. 7, 2017

Related U.S. Application Data
(60) Provisional application No. 62/347,079, filed on Jun. 7, 2016.

(51) Int. Cl. G11C 16/10; G11C 16/04; G11C 11/56; G11C 16/34; G11C 16/26

(52) U.S. Cl. CPC G11C 16/10; G11C 16/3459; G11C 16/26; G11C 11/5628; G11C 11/5671; G11C 11/5642; G11C 16/0483

(57) ABSTRACT

Provided are several preferred options of 3D hierarchical NAND arrays being formed in a (2D DL//3D LBL)_{⊥}(3D CSL//3D WL) scheme and their associated 2D PBs are preferably formed right below the 3D array but on the reversed side of Psub so that the large silicon areas of most 2D peripheral circuits can be saved and the various 3D nLC NAND operations can be performed in more powerful pipeline and concurrent manner with a dramatic reduction in latency and power consumption.

The preferred various 3D hierarchical NAND memories comprise a plurality of divided 3D sub-arrays for nLC storage, a plurality of 3D N-bit Cstring-based DCRs with minimum memory capacity to store 3×2n pages of program data when a 3-WL rotational nLC program scheme is adopted, and a plurality of distributed N-bit PBs with same number of LBL lines.

Each hierarchical 3D array comprises a plurality of 3D LGs and each LG comprises a plurality of 3D blocks connected by N local 3D LBL metal lines and 3D CSL lines and each block further comprises N strings without a need of extra local precharge line of LGps lines as disclosed in prior granted patents.

More number of distributed N-bit PBs would allow more powerful and flexible concurrent operations to be performed at the expense of taking larger silicon area in reversed side of Psub. By contrast, less number of distributed N-bit PBs would allow less powerful and flexible concurrent operations to be performed with a tradeoff of saving more silicon area in the reversed side of Psub. For performing any concurrent 3D NAND operation, a minimum two N-bit PB and 3×2n N-bit DCRs are required. Each N-bit SA comprises at least n+1 N-bit latches.

Each bit of PB comprises one SA and one nLC-latch circuit. N-bit SA further comprises one N-bit Current-sensing circuit for performing ABL program, ABL page data loading in each N-bit CLBLs, ABL program-verify, ABL read on each 3D sub-array and ABL Write-back to each N-nit Cstring-based DCRs, and one N-bit Voltages-sensing circuit for performing HBL Recall from each page of selected Cstring-based N-bit DCR to N-bit PB. The operations of the 3D hierarchical NAND and Cstring-based DCR arrays and their associated distributed PBs can be performed in both concurrent and pipeline manners, regardless of a 2-poly floating-gate 3D cell or a 1-poly charge-trapping 3D cell, regardless of GIDL or FN-tunneling erase scheme, regardless of SLC, MLC, TLC and XLC storage types.

### CROSS-REFERENCES TO RELATED APPLICATIONS

1. This application is the continuation of many U.S. Provisional and patent applications filed by same inventor of the present invention are commonly assigned and incorporated by reference herein for all purposes.

### TECHNICAL FIELD

The disclosures of the present invention relate to 3-dimensional (3D) semiconductor memories and, in particular, in one or more embodiments, the present disclosures relate more to various formations of plural distributed LBL-based 3D Hierarchical NAND memory arrays with plural distributed Cstring-based DCR arrays, and their associated distributed 2D LV PBs' SA circuit with both Current-sensing and Voltage-sensing inputs and Latch circuits preferably being formed in the reverse side of Psub. As a result, the peripheral silicon area can be dramatically reduced and a significantly powerful J-page NAND concurrent and pipeline operations can be performed. These preferred concurrent operations include Partial or Full 3D Erase, J-page ABL nLC program, J-page ABL program-verify, J-page ABL nLC read on the regular 3D hierarchical NAND arrays and J-page HBL Recall and J-page ABL Write-back on the distributed Cstring-based DCRs.

### BACKGROUND OF THE INVENTION

As it is well known, the further physical scaling capability of the 15 nm, planner, 2-poly floating-gate, 2D NAND non-volatile semiconductor memory device made of one unified array structure has encountered its device limit. The further NAND memory density increase has migrated to the 3D NAND.

Recently, however, 3D NAND memory devices have various methods of forming 3D NAND arrays and their associated peripheral circuits such as each PB that comprises one SA and plural latches. One of novel method disclosed by Micron is to form most of 3D NAND's peripheral CMOS devices such as PBs and block decoders, and others at the reverse side of Psub and right below the 3D NAND array to greatly improve overall NAND operations with dramatic die size reduction. Furthermore, due to the large area available below the large 3D NAND array in reversed side of Psub, more sets of N-bit PB circuits can be added and distributed within a die than the conventional 2D and 3D NAND designs so that more concurrent and pipeline operations can be achieved with less latency and power consumption.

But from inventor's study, the formations of Micron 3D NAND array and its associated peripheral circuits are still based on the conventional non-Hierarchical NAND structure by only increasing the number of PB and block decoders in the reverse side of Psub. Although the back-side of Psub has created more silicon areas to add the peripheral devices, it is still preferable to use the less area to achieve superior concurrent functions in less power consumption.

For the reasons sated above, and for other reasons stated below which will become apparent to those skilled in the art upon reading and understanding the present specification. There is a strong need in the art for alternate methods of forming and operating various distributed 3D hierarchical NAND arrays and 3D Cstring-based DCR array with their associated distributed peripheral circuits such as PBs, Block decoders and others being preferably formed in the reverse side of Psub, regardless of FN-tunneling or GIDL erase scheme, regardless of a 2-poly floating gate 3D NAND cell or a 1-poly charge-trapping 3D NAND cell, and regardless of J-page 1-WL nLC program or J-page 3-WL rotational nLC program.

### BRIEF DESCRIPTION OF THE DRAWINGS

FIG. 1 illustrates a of a portion of a first preferred 3D LG-based schematic representation of a 3D hierarchical NAND Array being equally divided into eight 3D sub-arrays with eight distributed 16 KB 2D PBs that are globally connected by 16 KB long top-level 2D DL lines. Each 16 KB 2D PB is further locally connected by 16 KB low-level ⅛-long 2D LBL lines being formed in parallel to 16 KB 2D DLs but perpendicular to 3D stings' 3D CSL lines and 3D WLs, e.g., referred as (DL//LBL)_{⊥}(CSL//WL) in accordance with the preferred concurrent operations of ABL nLC Program, ABL nLC Read, ABL nLC Program-verify, ABL nLC Erase-verify and nLC Erase of the present invention. Each 16 KB PB takes care of each divided ⅛ 3D sub-array and all eight distributed 16 KB PBs circuits are preferably formed below the preferred eight divided 3D hierarchical NAND sub-arrays to save silicon area.

FIG. 2 illustrates a of a portion of a second preferred 3D LG-based schematic representation of an alternate 3D hierarchical NAND Array being equally divided into four 3D sub-arrays associated with only four distributed 16 KB 2D PBs that are globally connected by 16 KB long top-level 2D DL lines and at least four additional 3D-string-based 4n×16 KB DCRs for storing 4n pages of nLC program data.

Each 16 KB 2D PB is shared by two 16 KB low-level ⅛-long local 2D LBL lines being formed in parallel to 16 KB DLs but perpendicular to 3D stings' 3D CSL lines and 3D WLs, e.g., referred as (DL//LBL)_{⊥}(CSL//WL) in accordance with the preferred concurrent operations of ABL nLC Program, ABL nLC Read, ABL nLC Program-verify, ABL nLC Erase-verify and nLC Erase of the present invention. Each 16 KB PB takes care of two divided ⅛ 3D sub-arrays and all four distributed 16 KB PBs and 4n×16 KB DCRs circuits are preferably formed below the preferred four divided 3D hierarchical NAND sub-arrays to save silicon area.

FIG. 3 illustrates a of a portion of a second preferred 3D LG-based schematic representation of an alternate 3D hierarchical NAND Array being equally divided into two 3D sub-arrays associated with only two distributed 16 KB 2D PBs that are globally connected by 16 KB long top-level 2D DL lines and at least eight additional 3D-string-based 8n×16 KB DCRs for storing 8n pages of nLC program data.

Each 16 KB 2D PB is shared by four 16 KB low-level ⅛-long local 2D LBL lines in two separate paired LGs being formed in parallel to 16 KB DLs but perpendicular to 3D stings' 3D CSL lines and 3D WLs, e.g., referred as (DL//LBL)_{⊥}(CSL//WL) in accordance with the preferred concurrent operations of ABL nLC Program, ABL nLC Read, ABL nLC Program-verify, ABL nLC Erase-verify and nLC Erase of the present invention. Each 16 KB PB takes care of two divided ⅛ 3D sub-arrays and all four distributed 16 KB PBs and 4n×16 KB DCRs circuits are preferably formed below the preferred four divided 3D hierarchical NAND sub-arrays to save silicon area.

FIG. 4 illustrates a schematic of a preferred 2D PB for all above preferred 3D hierarchical NAND Arrays. Each bit of PB is connected to each corresponding 3D LBL input via a HV 3D NMOS device of MN11 with one output of 2D DL to be connected to each bit of a LV CACHE shared by all PBs. Each PB comprises one LV 2D TLC-latch circuit (86), one LV 2D SA circuit (104a) that can perform both ABL-current sensing and HBL-DRAM sensing in different cycle with minimum number of transistors, one PRE circuit (106) and one Match circuit (107) for performing Program-verify.

FIG. 5 illustrates a detailed schematic of a preferred 1-bit LV 2D TLC Latch circuit (86) of each bit of a LV 2D PB. For SLC or MLC Latch circuit, the number of latches can be reduced one or two accordingly.

FIG. 6 illustrates a detailed schematic of a preferred 1-bit LV 2D Match circuit (107) with 3 CODE inputs of 3 TLC pages of MSB, CSB and LSB of each bit of a LV 2D PB. For SLC or MLC Latch circuit, the number of Code inputs is reduced to one or two accordingly.

### SUMMARY OF THE INVENTION

A principle objective of the invention is to form various distributed CLBL-based LGs 3D Hierarchical NAND arrays associated with a plurality of the distributed 3D Csting-based N-bit 3D DCRs and a plurality of distributed N-bit 2D LV PBs and other peripheral circuits to be formed right below 3D NAND and distributed 3D DCR arrays but in the reversed side of Psub to allow multiple 3D NAND operations to be performed in pipeline, concurrent or the mixed manners with a dramatic reduction in silicon area and power consumption.

Another objective of the invention is to use only HV 3D NMOS devices such as a 3DML transistor as a HV buffer to connect each local HV 3D LBLo/e metal line to each corresponding shared LV 2D GBLo/e metal line controlled by a gate signal of LG, to use a HV 3DMD NMOS transistor to connect each local HV 3D DCRo/e metal line to each corresponding shared LV 2D GBLo/e metal line controlled by a gate signal of ENDCR, and a HV 3DMT NMOS transistor acting as a switch between two adjacent LGs' LBL lines controlled by a gate signal of TIE. The HV means Verase or Vpgm with a value up to 25V.

Yet another objective of the invention is to form all various preferred Hierarchical 3D cell arrays and the distributed Csting-based 3D DCR arrays with at least two or more than two distributed N-bit LV PBs being preferably formed right below above two 3D arrays but in the reversed side of the Psub to save the most of the silicon areas of peripheral circuits.

A still further objective of the invention is to use one 3D NAND string's channel capacitance (Cstring) as 1-bit DCR to store 1-bit nLC digital program data with Vdd voltage for “1” data and Vss voltage for “0” data. All 3D cells' Vts in each Cstring of DCR are preferably kept as Vte, which is the erase-state Vt with a value below 0V, e.g., Vte<0V. As such, each Cstring capacitance of each bit of DCR can reach the maximum value referred as Cstringmax when all 3D WLs of all N-bit DCR blocks are tied to Vdd but with VSSL=VGSL=0V to prevent the each stored voltage of each bit of program data from being leaked.

Note, the location of every distributed 3D DCR is preferably placed nearing each corresponding distributed 2D PB to keep the short 3D DCRo/e metal line so that the highest signal voltage level after each Charge-sharing (CS) operation of each HBL Recall operation can be achieved. The CS is performed between each 3D Cstring and each corresponding 3D DCR metal with a capacitor ratio defined as the equation of R=Cstring/(Cstring+CDCR). For today's 3D NAND technology, the maximum number of cells in each Cstring is 48 which makes Cstring comparable to CDCR, thus high value of R.

A still further objective of the invention is to execute an immediate concurrent ABL SLC program on all Cstring-based DCRs that store the 3-WL nLC program 3×2n×N-bit page data when Vdd supply's unintentional power-down is being detected and the desired nLC 3-WL rotational program is not completed yet. Note, the ABL SLC program is only performed on those erased cell of DCRS' WLs with incomplete nLC ABL program in the regular 3D NAND array in accordance with on-chip state machine record and control.

A still further objective of the invention is to design each SA circuit of each bit of PB having two sensing independent inputs such as a Current-sensing input to be used for a preferred N-bit ABL Read and another Voltage-sensing input to be used for a preferred-bit HBL Recall operation in two different cycles.

A still further objective of the invention is to allow two different sensing to be performed concurrently in at least two more than two different N-bit distributed PBs according to different NAND operations.

For example, at least one N-bit PB's N-bit SA may perform Voltage-sensing of a HBL Recall operation, while at least one another PB's N-bit SA is performing Current-sensing of an ABL Read operation simultaneously, independently and locally. Since a HBL Recall and an ABL Read are done locally in different LGs in each distributed PB, thus no data contention will occurs on N-bit shared DL metal lines.

A still further objective of the invention is to add 2D CMOS circuits to each PB circuit (Not shown) in FIG. 4 can generate three desired voltages of a Program-inhibit voltage of Vdd, a Coarse program voltage of 0V, and a Fine program voltage of 0V<VLBL<1V that can be fully passed to each selected 3D cell's channel in the selected 3D string and block via each corresponding GBL and each LBL metal during ABL nLC program operation, where Coarse nLC program-verify voltage is Vtn, and the Fine nLC program-verify voltage is about Vtn-0.2V.

A still further objective of the invention is to perform the first preferred concurrent J-page 3D HBLo/e (Half-BL) Program-verify operation on J distributed N-bit cells of J selected WLs of the 3D hierarchical NAND array, where J=1 to 8 in accordance with the number of the distributed PB is 1 to 8. Each HBL program-verify operation can be split into 4 sequential steps below.
1) Perform HBL Recall of N/2-bit of each page of nLC data from N/2-bit corresponding GBLo/e of each N/2-bit DRCo/e's Cstrings/e sequentially into PB for data comparison.
2) J×N/2-bit CLBLo/e precharge for HBL program-verify and J×N/2-bit CLBLe/o shielding lines concurrent operation step:

Initially, all J-page N/2-bit of CLBLo/e are precharged from LGpso/e to 1V (VLBLo/e=1V) but the remaining N/2-bit interleaved CLBLe/o are held at 0V acting as the shielding lines during HBL LBLo/e Read.
3) Concurrent J×N/2-bit LBLo/e cells' Vt evaluations step: It is performed to J×N/2-bit LBLo/e cells with appropriate set of WLs, SSL and GSL voltages such as VR, Vread and Vdd per selected WL per selected LG. This is a major latency of each HBL program-verify step with the following evaluation results within preset of each iterative program-verify time.
   a) Pass Fine program-verify: Once cells' Vts pass the verify condition of Fine program Vt of Vtn-0.2V, then VLBL=1V.
   b) Fail Fine program-verify: Once cells' Vts fail the verify condition of Fine program Vt of Vtn-0.2V, then VLBL=0V after the preset period time.
4) A DRAM-like CS (charge-sharing) between one selected CLBL and one CGBL.
   a) Pass Fine program-verify: VLBL=VGBL=1V×R, where R is the CS ratio with an equation of R=1V×CLBC/(CLBL+CGBL).
   b) Fail Fine program-verify: Once cells' Vts fail the verify condition of Fine program Vt of Vtn-0.2V, then VLBL=VGBL=0V after the preset period time.
5) Fine or Coarse program-verify:
   a) Once cells' Vts fail the verify condition of Fine program Vt of Vtn−0.2V, then VLBL=0V after the preset period time.
   b) Once cells' Vts pass the verify condition of Fine program Vt of Vtn−0.2V, then set 0V<VLBL<1V after the preset period time.
   c) Once cells' Vts pass the verify condition of final program Vt of Vtn, then set VLBL=Vdd to inhibit the next iterative program.
6) Continue the 2^{nd} HBL J×N/2-bit program-verify
7) Check if J×N-bit ABL program is passed? If it passes, then ABL nLC program is completed. Otherwise, the J×N-bit ABL nLC program is continued until the set count number is reached, then it is stopped to report a bad 3D block.

A still further objective of the invention is to perform the preferred concurrent J-page 3D ABL CLBL Read operation with steps like above program-verify by J distributed PBs but without those interactive steps, where J=2 to 8.

A still further objective of the invention is to perform the preferred concurrent J-page mixed or same operations such as Partial/Full-block Erase, ABL nLC Program, ABL nLC Program-verify, ABL nLC Read, ABL Erase-verify in different 3D LGs of the preferred 3D Hierarchical NAND arrays.

A still further objective of the invention is to form those HV 3D devices such as 3DML, 3DMD and 3DML NMOS transistors to connect respective paired 3D LBL lines and one 3D DCR

A still further objective of the invention is to provide a flexible Program size in unit of K×N-bit, where K is the number of selected 3D/2D WLs for performing ABL nLC concurrent program and K is Integer and defined as K≧1 in accordance with PB size is N-bit.

A still further objective of the invention is to remove the MHV of Vread from the non-selected WLs of the selected 3D blocks when each ABL Read data is being sensed and latched into each corresponding SA so that the WL Vread-stress can be dramatically reduced due to the faster Read speed with less LBL capacitance of the preferred 3D/2D hierarchical NAND array.

A still further objective of the invention is to build n on-chip ECC circuit to be shared by all J distributed PBs after J-page ABL nLC program-verify operations of any ECC algorithms are performed. The ECC circuit will count if the total number of error bits of each selected 3D WL of the selected page exceeding the preset maximum number of N bits of nLC page data plus Syndrome bits?

### DETAILED DESCRIPTION OF EXEMPLARY EMBODIMENTS

In the following detailed descriptions of concurrent operations, the present 3D hierarchical NAND array and the associated 3D Cstring-based DCRs embodiments, reference is made to the previous pending utilities or provisional ones filed the same inventor and the following accompanying drawings that forms a part hereof, and in which is shown, by way of illustration, specific embodiments in which the disclosure may be practiced. In the drawings, like numerals describe substantially similar components throughout the several views. These embodiments are described in sufficient detail to enable those skilled in the ordinary art to practice the embodiments. Other embodiments may be utilized and any structural, logical, and electrical changes may be made without departing from the scope of the present disclosure. The following detailed description, therefore, is not intended to be exhaustive or to be limited to the precise form disclosed.

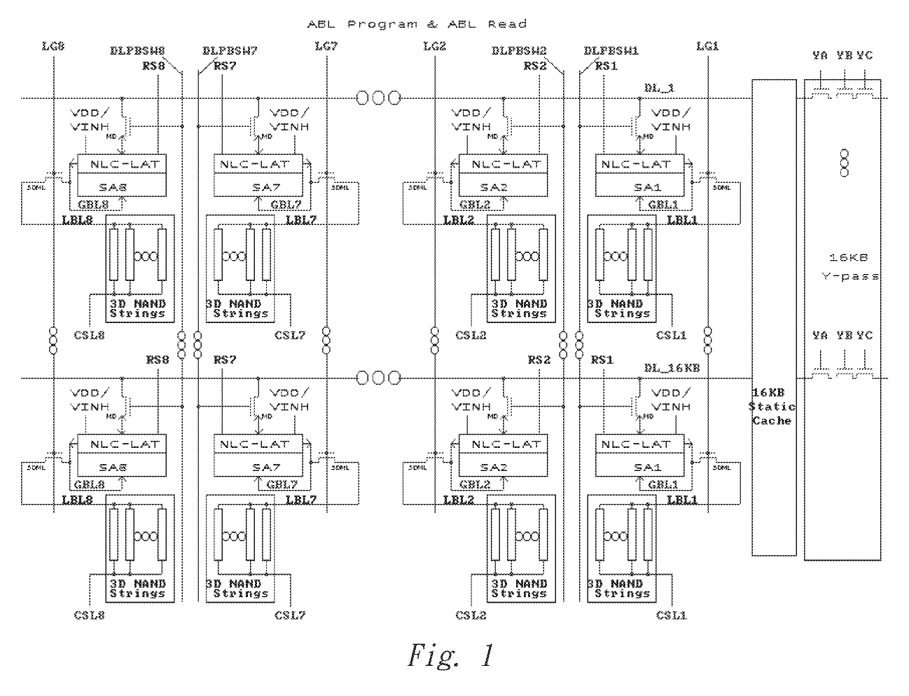

In the following descriptions, when a N-bit ABL nLC ABL Program is referred, it means that total N-bit 3D NAND cells, not including the additional syndrome ECC bytes, formed on one 3D WL and more than one physical 3D WLs of plurality of selected 3D strings in the selected 3D LGs being concurrently selected for performing J-page nLC ABL program along with one or more than local distributed N-bit PB and N-bit DRCs of all preferred 3D Hierarchical arrays from FIG. 1A, FIG. 1B and FIG. 1C and the likes not shown.

For example, a full physical 3D WL page size is formed with 8 KB physical 3D cells. Thereby, one option of an ABL nLC program with 16 KB size means two physical WLs of 8 KB size are concurrently selected for nLC program with 8 KB PB of the present invention. Unlike prior art using 16 KB PB (Page-Buffer) to perform one 16 KB ABL nLC program, only 8 KB PB is required to perform 16 KB ABL nLC program of the present invention. Thereby, the PB size is cut in half for a 50% saving in silicon area.

Furthermore, when a nLC ABL Program-verify and ABL Read are referred in the following descriptions, it means that N-bit cells per one 3D WL, per one selected 3D string, per one selected 3D block in one selected 3D LG, are selected for performing concurrent ABL Program-verify and ABL Read by N-bit locally corresponding distributed SAs that use one Current-sensing scheme to eliminate the undesired LBL-LBL, GBL-GBL and DL-DL AC Read coupling effect. To Read and Program-verify one page of N-bit nLC data from one selected 3D WL of one selected 3D block, only a 1-cycle ABL Read is required. Similarly, a ABL Write-back by each N-bit distributed SA from each N-bit PB to each N-bit Cstring-based DCR for each nLC digital page data, only a 1-cycle ABL Read is required.

By contrast, when a nLC HBL Recall is referred, it means that N/2-bit interleaved cells per one 3D WL, per one selected 3D string, per one selected 3D block of each Cstring-based DCR are selected for performing concurrent DRAM-like read so that the undesired DCR-DCR metal line AC Read coupling effect can be eliminated. To Recall one page of N-bit nLC digital data from one selected 3D WL of one selected 3D Cstring-based DCR, a 2-cycle HBL Recall is required.

To Recall one page of Cstring-based N-bit locally distributed nLC data from each corresponding locally distributed N-bit 3D DCR to N-bit PB, a 2-cycle HBL Recall is required via N/2-bit selected locally distributed LBL metal lines.

By contrast, to Write-back one page of N-bit nLC digital data from N-bit locally distributed PB to N-bit Cstring-based locally distributed DCRs, only a 1-cycle ABL Write-back is required via N-bit selected locally distributed LBL metal lines.

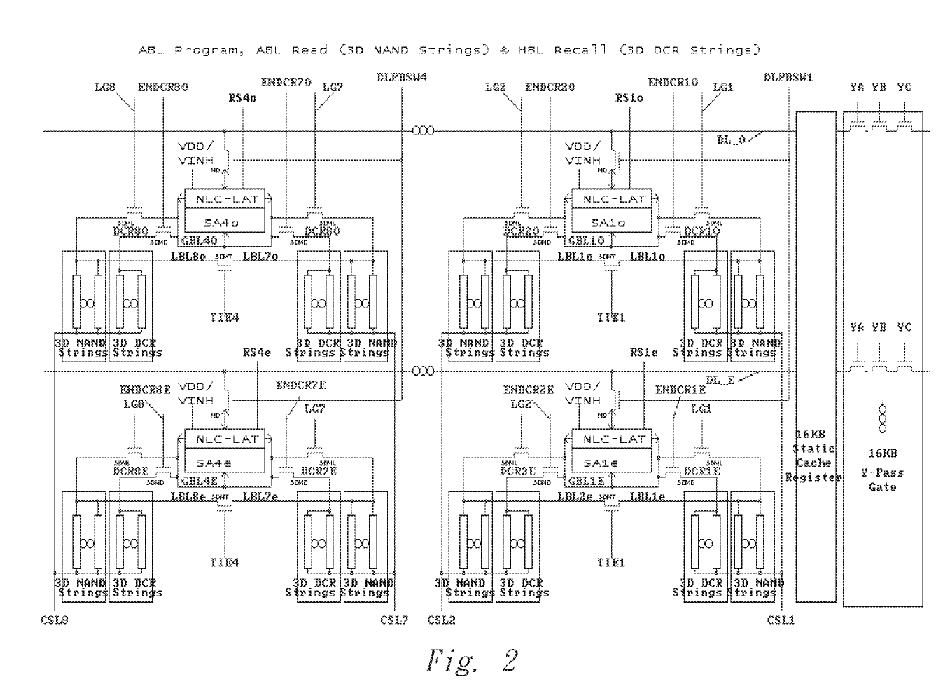

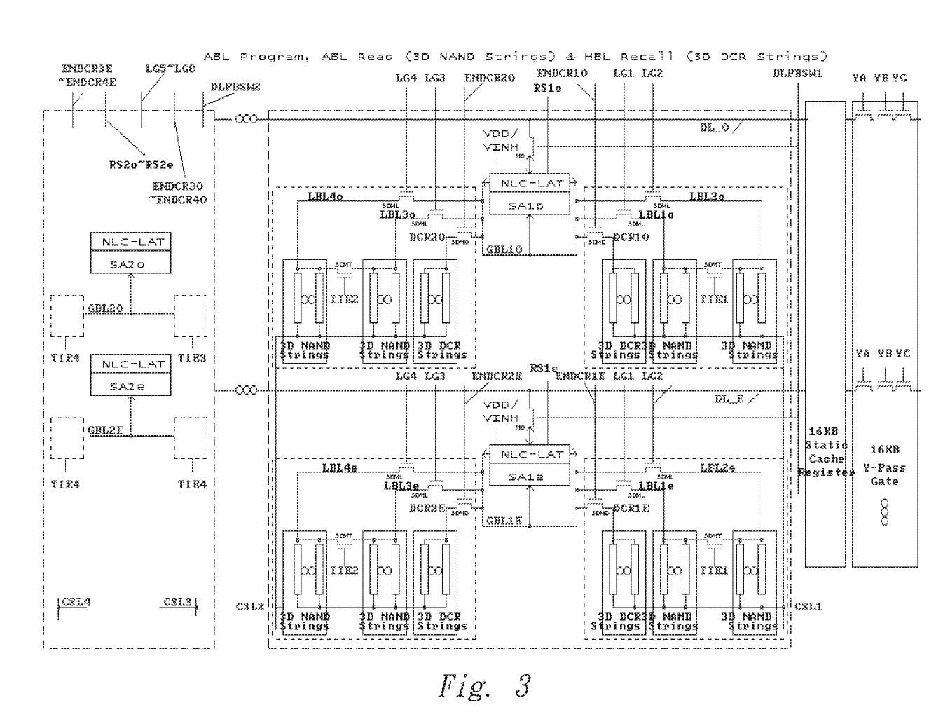

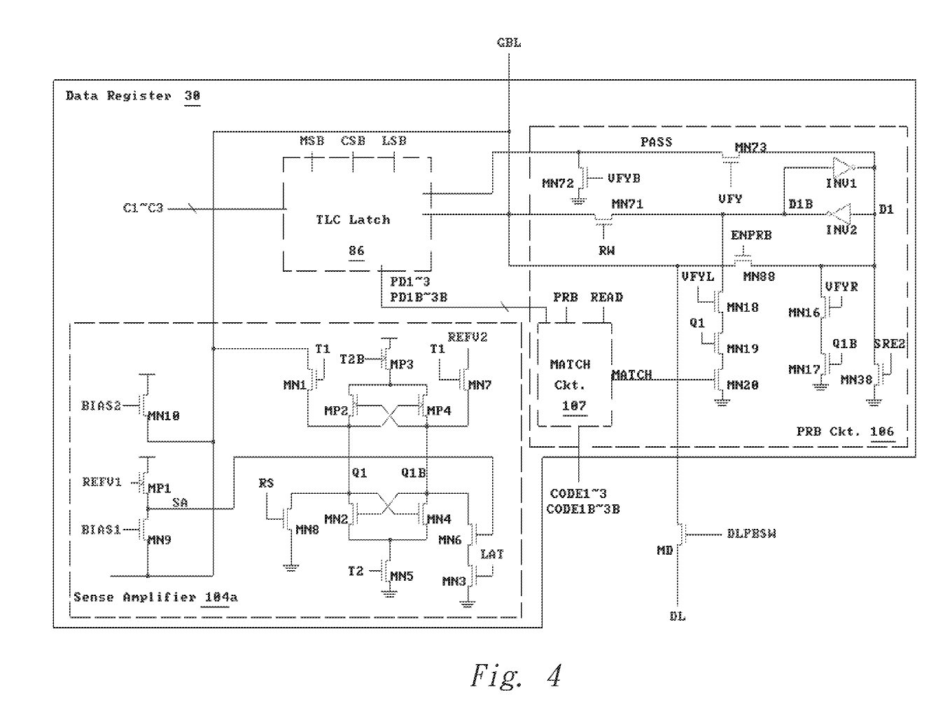

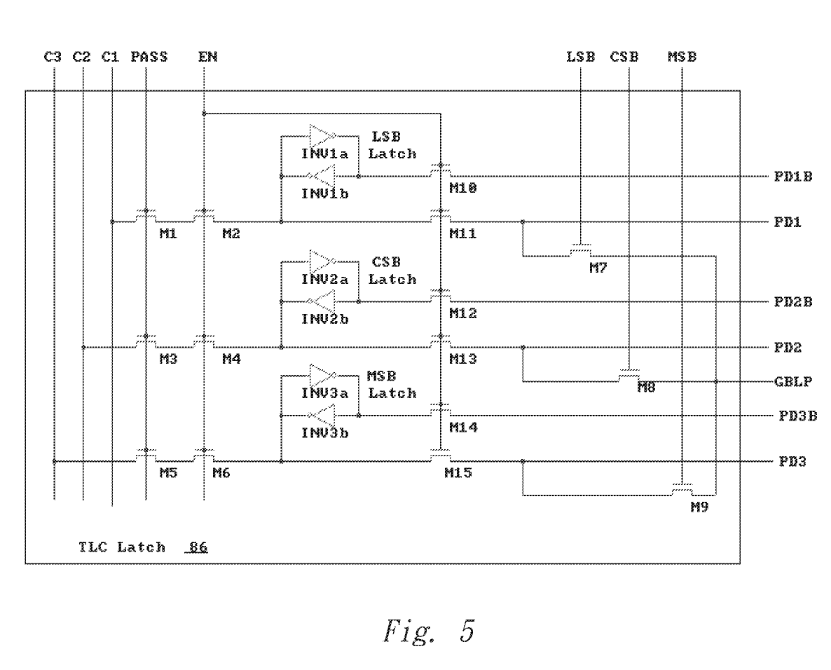

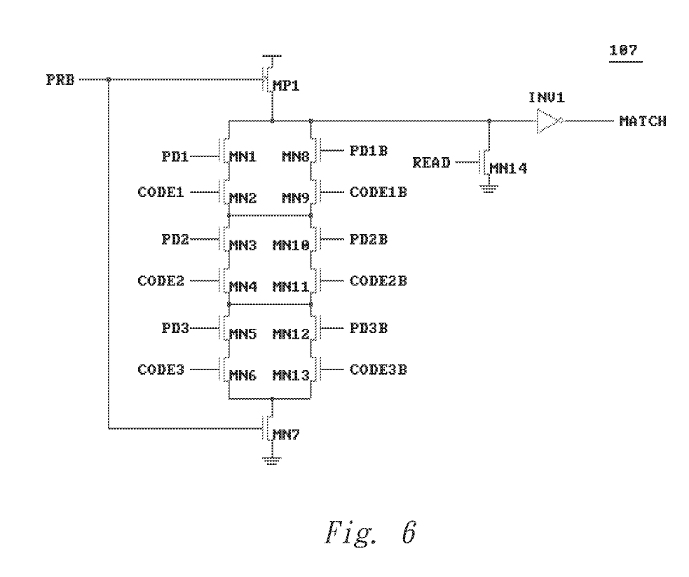

Furthermore, when a 3D NAND cell is referred in the following descriptions, it means that either a 2-poly Floating-gate 3D NAND cell or a 1-poly Charge-trapping 3D NAND cell is used in 3 preferred 3D Hierarchical NAND arrays with a plurality of distributed 2D PBs and 3D Cstring-based DCRs of FIG. 1, FIG. 2, FIG. 3 and the likes of the present invention.

Furthermore, when a 3D NAND Erase operation is referred in the following descriptions, it means either a FN channel-tunneling erase scheme or a GIDL erase scheme is used in above 3 preferred 3D Hierarchical NAND arrays with a plurality of distributed PBs and DCRs of FIG. 1, FIG. 2, FIG. 3 and the likes of the present invention.

Furthermore, when a locally distributed PB is referred in the following descriptions, it means a LV N-bit PB comprising of one nLC Latch circuit (86), one LV SA mixed with N-bit current-sensing LV SA for ABL Read and Verify and one N-bit voltage-sensing LV SAs for HBL Read and Verify (104a), one LV PRB circuit (106), one LV Match circuit (107). All devices of each PB circuit in FIG. 4 are preferably formed on the reverse side of the Psub to save silicon area.

Although particular embodiments of above preferred 3D hierarchical NAND arrays and distributed PBs and DCRs to perform the mixed pipeline and concurrent operations will be disclosed below, other derivatives, modifications and changes from the present invention will be apparent to those of ordinary skill in the art and should be covered by this invention. Some embodiments have been covered in previous U.S. patent applications by the same inventor of this invention and are omitted here for description simplicity. Only the new inventive concepts are summarized below as the targeted objectives.

Embodiments of the semiconductor memory devices and Hierarchical arrays are described with reference to the drawings.

FIG. 1 illustrates a portion of a first preferred 3D LG-based schematic representation of a 3D hierarchical NAND memory that comprises eight (8) divided 3D sub-arrays, eight (8) distributed 16 KB PBs. Each bit of PB further comprises one 16 KB SAs, and eight nLC-latch circuits

Array being equally divided into eight 3D sub-arrays with eight distributed 16 KB 2D PBs that are globally connected by 16 KB long top-level 2D DL lines, which are formed on the reversed side of Psub right below eight locally distributed 16 KB-width 3D sub-arrays.

Each 16 KB 2D PB comprises 16 KB 2D LV SAs circuit distributed in ⅛ of whole 3D hierarchical 3D array and their associated 16 KB 2D, LV, nLC Latches. Each 3D ⅛-array further comprises a plurality of 3D NAND blocks. Each 3D NAND block further comprises a plurality of 3D NAND strings with their 16 KB drains being locally connected by 16 KB low-level ⅛-long 3D LBL metal lines being formed in parallel to 16 KB long 2D DLs and their 16 KB sources being connected to one common 3D CSL metal lines in parallel to 3D WLs but perpendicular to LBL and DL lines, e.g., referred as (2D DL//3D LBL)_{⊥}(3D CSL//3D WL) in accordance with the preferred concurrent operations of ABL nLC Program, ABL nLC Read, ABL nLC Program-verify, ABL nLC Erase-verify and nLC Erase of the present invention. Each 16 KB PB takes care of each divided ⅛ 3D sub-array and all eight distributed 16 KB PBs circuits are preferably formed below the preferred eight divided 3D hierarchical NAND sub-arrays to save silicon area.

Each local 3D LBL metal line is connected to each corresponding input of GBL1 of each 2D SA through one HV (>20V) 3D NMOS transistor (3DML) with its gate being tied to a common LG1 signal, its drain tied to LBL1, and its source tied to GBL1. Each output of nLC-Latch circuit is then coupled to the corresponding drain node of a LV 2D NMOS MD transistor with its gate being coupled to a common DLPBSW1 signal and its source being connected to each corresponding 2D DL.

Each SA circuit is shown in FIG. 4 with one corresponding input of 2D GBL metal with multiple connections as explained below.
1) The first connection to each corresponding 3D LBL of each correspond ⅛ 3D arrays.
2) The second connection to each corresponding input of a LV SA circuit (104a).
3) The third connection to each corresponding bidirectional input of a LV PRB circuit (106).
4) The fourth connection to each corresponding input of a LV TLC Latch circuit (86).

The whole 3D NAND memory only uses one 16 KB static CACHE, whose 16 KB bidirectional inputs are connected to 16 KB corresponding DLs and can be sequentially shared by eight distributed 16 KB PBs. Furthermore, only one bidirectional 16 KB Y-pass circuit with a 3-level column decoding of YA-dec, YB-dec and YC-dec is connected to 16 KB outputs of the static CACHE. As a result, either one Byte or one Word can be decoded to Byte-based or Word-based I/Os of NAND memory (Not shown).

Now, the details of the concurrent operations of FIG. 1 will be explained below.
1) Sequential data loading during nLC ABL program:
   a) Only 1-page of 16 KB ABL nLC program: In this case, n×16 KB nLC page data will be sequentially loaded from a NAND's Byte-based I/Os to one of the selected distributed PB that is configured to have at least n×16 KB latches in n×16 KB cycles via Y-pass and 16 KB static CACHE (SCACHE).
      In real operation, the first step is to load one of 16 KB nLC page data into the SCACHE by 16K sequential cycles.
      Next, each 16 KB page data in SCACHE is synchronously loaded into one 16 KB latches of one selected PB via 16 KB DLs and 16 KB corresponding MD transistors by setting one of VDLPBSW≧Vdd+Vt in a parallel manner in 1-cycle so that a full passage of Vdd of a program-inhibit voltage for data “1” or Vss of a program-voltage for data “0” can be achieved.
      Third, each nLC page data loading will be repeated n times to fully load n×16 KB nLC data into one selected 2D PB that contains one selected 3D WL comprising 16 KB 3D NAND cells in one selected 3D block inside one selected 3D LG, where n=1 for SLC, n=2 for MLC, n=3 for TLC and n=4 for XLC storages. No concern of any DL-DL AC coupling effect during this lengthy nLC data loading.
   b) Up to 8-page of 16 KB ABL nLC program: In this case, total 8n×16 KB nLC page data will be sequentially loaded from a NAND's Byte-based I/Os to all eight selected distributed PBs in 8n×16 KB latches in 8n×16K sequential cycles. I other words, the steps of a) will be repeated up to 8 times. The details are skipped here for description brevity.
2) ABL nLC program:
   a) Only 1-page of 16 KB ABL nLC program is performed without a rotational program in 3 adjacent 3D WLs:
      In this case, n×16 KB nLC page data will be sequentially programmed into 16 KB 3D cells simultaneously in one iterative cycle of one selected 3D WL. n pages of each nLC program data will require n cycles. There are many different ways to program each page of nLC data from one selected 16 KB PB to one selected 3D WL with 16 KB 3D cells. Note, this no rotational 3-WL ABL nLC program is to neglect the 3D cells' Vt DC coupling effect between 3 physically adjacent 3D WLs in 3 different heights. In this case, each bit of PB's nLC-latch circuit only requires storing one nLC page data. For a SLC/MLC/TLC ABL program, each bit of each PB requires 1/2/3 latches respectively.
   b) A 3-page of 16 KB ABL nLC program is rotationally performed in 3 physically adjacent 3D WLs to mitigate 3D cells' DC Vt coupling effect in 3 adjacent WLs in 3 different heights: This method means the 3D cells' DC Vt coupling effect between three adjacent 3D WLs is not negligible.
      In this case, 3×n×16 KB nLC page data will be sequentially programmed into three 16 KB 3D cells simultaneously in three selected adjacent 3D WLs. 3n pages of nLC program data are required to be stored in each bit of PB in 3×n cycles. In this case, each bit of PB's nLC-latch circuit requires 3×n×16 KB nLC page data to be stored in one bit of PB. For a SLC/MLC/TLC ABL program, each bit of PB requires 3/6/9 latches respectively. Thus, this 3-WL rotational ABL nLC program scheme will increase the size of each PB's nLC-latch circuit by 3×. In the future, a 100-layer 3D string will become the mainstream. Thus, the physical spacing between two adjacent 3D WLs will get smaller and smaller. As a result, the 3D cells' Vt DC coupling effect between three adjoined 3D WLs will greatly degrade the stored nLC data. Thus, a popular 2D's 3-WL rotational ABL program scheme is or will be adopted in the mainstream 3D NAND ABL nLC program. Thus, the size reduction of each PB's nLC-latch circuit for a 3-WL rotational ABL nLC program in a 3D hierarchical array is strongly required.
      Therefore, a 3D string-based capacitor, Cstring, to store n−1 nLC program data is used. Each page of 16 KB Cstrings is referred as Dynamic CACAHE or 3D DCR. The reading of this 16 KB DCACHE digital data is performed in a HBL manner in 2 cycles. The 2-cycle reading is defined as HBL Recall and each 16 KB digital data writing into each 16 KB DCACHE is performed in ABL manner in 1-cycle by each 16 KB PB and defined as an ABL Write-back. In order to perform a HBL Recall, each SA of the present invention needs to have a DRAM-like voltage sensing circuit as shown in FIG. 4 with one reference input of REFV2 to one input node of Q1B of a latch-type SA (104a) and data input node to Q1 from each GBL node via a paired NOS devices of MN7 and N1 during one one-shot T1 sensing cycle.
3) ABL nLC program-verify operation: This operation is preferably split into two sub-operations as listed below.
   a) A 2-cycle HBL DCACHE Recall operation first to read out one page of 16 KB nLC page digital data that is stored in a DRAM-like capacitor-Cstring in a 16 KB DCACHE into n×16 KB PB's nLC-Latch circuits (104a) for subsequent iterative ABL program-verify's nLC data comparison purpose. The DRAM-like Voltage-sensing SA's input that comprises one LBL precharge sub-circuit of MN10 with its gate being tied to BIASE2 and one ABL Current-sensing circuit being biased at off-state. The Current-sensing circuit comprises one p-load transistor of MP1 with its gate being tied to a reference voltage of REFV1 in series with one LV NMOS transistor of MN9 with its gate tied to BIAS1. The Voltage-sensing input is the source node of MN10, which is coupled to each corresponding GBL and is connected to each corresponding LBL node of each selected LG.
b) A 1-cycle ABL 16 KB program-verify is performed on one selected 3D WL's 16 KB cells by using each SA's Current-sensing circuit that comprises one LBL precharge sub-circuit of MN10 with its gate being tied to BIASE2 and one Current sensing p-load transistor of MP1 with its gate being tied to a reference voltage of REFV1 in series with one LV NMOS transistor of MN9 with its gate tied to BIAS1. The Current-sensing input is the source node of MN9, which is coupled to each corresponding GBL and is connected to each corresponding LBL node of each selected LG. Note, for a HBL Recall operation, both the Current-sensing precharge circuit of MN10 and the Voltage-sensing circuit of MP1 and MN9 are required.
4) Concurrent up to 8-page nLC operations:
   Any one or more than one of 3D ⅛-array and its associated one 16 KB distributed LV PB can be independently performed one of several key 3D NAND operations such as ABL nLC program, ABL nLC read, ABL nLC program-verify, erase, HBL erase-verify, or ABL 16 KB loading from 16 KB SCACHE, HBL Recall, ABL Write-Back with a strict rule no two operations using one 16 KB DLs. In other words, no data contention is allowed in the shared global 16 KB DLs or in the shared local LBL and GBL lines, or in the shared SCACHEs, or in the shared set of global WLs, SSL and GSL lines during all different kinds of the preferred concurrent operations.

FIG. 2 illustrates a portion of a second preferred 3D LG-based schematic representation of an alternate 3D hierarchical NAND memory that comprises only four (4) divided bigger 3D ¼-arrays, four (4) distributed same size of 16 KB PBs. Each bit of PB is shared by one paired physically and electrically identical 3D ⅛-arrays and 3D-DCRs with same PB's circuit connections separately in two independent 3D LGs. The plural drain nodes of all strings of ⅛-3D-array in LBL or DL direction are respectively connected by the first short 16 KB 3D LBLo/e metal1 lines and then connected to corresponding 16 KB SAo/e sensing-current inputs via 16 KB corresponding 2D GBLo/e metal1 lines. Likewise, another plural drain nodes of all strings of 3D-DCRs in LBL or DL direction are also respectively connected by the short 16 KB 3D DCRo/e metal1 lines in same level of 3D LBLo/e metal1 lines and then connected to corresponding 16 KB SAo/e voltage-sensing inputs via 16 KB corresponding first 2D GBLo/e metal1 lines.

Each bit of PB in FIG. 2 comprises one identical circuit of nLC-latch circuit and one SA containing both current-sensing and voltage-sensing inputs. Each SA's current-sensing input is used to perform ABL 16 KB nLC read in 1-cycle from one selected block's 16 KB 3D strings of one paired ⅛-3D-arrays. By contrast, each SA's voltage-sensing input is used to perform HBL 8 KB nLC page's digital data from of one 8 KB Odd/Even 3D-strings of one paired 3D-DCRs.

The size requirement of each 3D-DCR comprises at least 3×2n×16 KB DCR strings to allow the minimum storage of 3×2n×16 KB nLC digital page data for performing a desired 3-WL rotational nLC program scheme for this 3D hierarchical NAND array of the present invention. The reasons for 3×2n×16 KB Cstrings are explained below.
1) For each ABL nLC program for each selected 3D WL, it requires n×16 KB program data to be stored locally in the 3D-DCRs.
2) For a HBL Recall operation, it requires 2n×8 KB 3D-DCRs' strings to store two separate n×8 KB Odd/Even program data to avoid DCRo/e-DCRo/e metal coupling effect.
3) For a 3-WL rotational ABL nLC program, it requires 3×2n×16 KB program data to be stored locally in the 3D-DCRs.

The 3D hierarchical NAND array in FIG. 2 is also equally divided into four bigger 3D ¼-arrays that are globally connected by same 16 KB long top-level 2D DL metal lines, which are formed on the reversed side of Psub right below eight locally distributed 16 KB-width 3D sub-arrays.
Each 3D ¼-array is further divided into one paired of 2 physically separate smaller 3D ⅛-arrays like FIG. 1. Similarly, each 3D ⅛-array further similarly comprises a plurality of 3D NAND strings as FIG. 1 with their 16 KB drains being locally connected by 16 KB low-level ⅛-long 3D LBL metal lines being formed in parallel to 16 KB long 2D DLs and their 16 KB sources being connected to a plurality of common another 3D CSL metal lines in parallel to 3D WLs but perpendicular to LBL and DL lines, e.g., referred as (2D DL//3D LBL)_{⊥}(3D CSL//3D WL) in accordance with the preferred concurrent operations of ABL nLC Program, ABL nLC Read, ABL nLC Program-verify, ABL nLC Erase-verify, HBL Recall, ABL write-back and nLC Erase of the present invention. Since only four 16 KB PBs are shared by eight ⅛-arrays, thus peripheral silicon area is further cut more than half if 3-WL rotational nLC program scheme is adopted for the 3D Hierarchical array concurrent operations.

In addition, a 3D HV NMOS transistor is inserted between each paired 3D LBLo/e metal lines with its gate being tied to TIE is proposed by the present invention. The reason to incorporate this HV transistor is to allow the CS (Charge-sharing) or LBLo/e precharge operation between two physically separate 1/8-array can be performed to generate the desired plural Analog VLBLs with ΔVBL=ΔVtn of nLC Vtn for a superior ABL nLC program as disclosed by the same inventor in plural prior inventions in both 2D and 3D hierarchical NAND arrays. The details can be referred to many previous patents granted to the same inventor of the present invention. Thus the detailed explanations are omitted herein for description brevity.
Now the detailed operations of ABL program and Read of FIG. 2 are explained below.
1) Concurrent ABL nLC program:
   Like FIG. 1 to perform 8-page ABL program concurrently but using only 4 16 KB PBs in FIG. 2, then 8 CLBL-based capacitors to store 8 pages of nLC data per each iterative program cycle are used.
   a) Load and latch 8×16 KB page data of 8 nLC page data into 8 CLBLs sequentially in 8 cycles from I/O, through 16 KB common DL lines and 16 KB SAs in each PBs.
   b) Simultaneously load and latch 8×16 KB page data of 8 nLC page data into 16 3D-DCRs strings in 16 cycles sequentially from I/O, through 16 KB common DL lines and 16 KB SAs in each PBs. Note a) and b) can be done on the same time.
   c) The selected set of preferred WLs, SSL and GSL voltages of each iterative program are coupled to multiple selected 3D blocks to allow the concurrent ABL program of the first page nLC data can be started and performed.
      Conclusion: Using 4 PBs but 8 CLBLs per one DL in FIG. 2 can perform up to 8-WL concurrent nLC program as FIG. 1 to further reduce the peripheral silicon area with same nLC program capability.
2) Concurrent ABL nLC Read or ABL nLC program-verify:
   Unlike FIG. 1 to perform 8-page ABL 16 KB read concurrently due to 8 PBs are available. But only 4-page concurrent ABL read can be performed in FIG. 2 due to only 4 PBs are available. But FIG. 2 does not slow down ABL read latency at all as compared to FIG. 1 as viewed from Off-chip Flash controller. The reason is because only one set of 16 KB DLs is shared by 4 distributed 16 KB PBs. The passage of each 16 KB nLC data from each corresponding ⅛-array to I/O can only be done 1-PB by 1-PB sequentially from four 16 KB PRB circuit (106). During the sequentially transferring four large 16 KB data from PRBs to I/Os, another four 16 KB data of next page of ABL read operation can be simultaneously performed in four separate 16 KB SAs current-sensing circuits. Once the first 4-page nLC data being sequentially and fully sent out to the Off-chip Flash controller, the next 4-page data from same four PBs can be transferred to same four 16 KB PRBs in parallel manner in 1-cycle to be ready for subsequent transferring to I/Os. Thus, FIG. 1 and FIG. 2 will have same Read and Program latency but FIG. 2 has reduced the PBs' size to 50%.
3) Up to 8-page Concurrent nLC different operations:
   Any one or more than one of ⅛-array and its associated one 16 KB distributed LV PB can independently perform one of several key 3D NAND operations such as ABL nLC program, ABL nLC read, ABL nLC program-verify, erase, HBL erase-verify, or ABL 16 KB loading from 16 KB SCACHE, HBL Recall, ABL Write-Back complying with a strict rule no two operations using one common set of global 16 KB DLs, one common set of local 16 KB LBLs, one common set of 16 KB DCRs and common PBs at the same time during all different kinds of the preferred concurrent operations. The rest of detailed bias conditions and steps of each key concurrent operation are same, thus are same for both FIG. 1 and FIG. 2. thus are omitted herein for brevity.

FIG. 3 illustrates a portion of a third preferred 3D LG-based schematic representation of an alternate 3D hierarchical NAND memory that comprises only four (4) divided bigger 3D ¼-arrays and two (2) distributed same size of 16 KB PBs. Each PB is shared by two physically separated 3D TIEs. Each 3D TIE further comprises two independent 3D ⅛-arrays and one 3D-DCR connecting to one common GBLo/e line via three different HV transistors 3DML controlled by two sets of three gate signals such as
1) Each SA1o/e has one common input node of GBL1o/e shared by 2 sets of control signals below:
   a. LG4, LG3 and ENDCR2o/e.
   b. LG2, LG1 and ENDCR1o/e.
The first plural drain nodes of all 3D strings of first four 3D ⅛-arrays formed in four respective LG4, LG3, LG2 and LG1 are respectively connected by LBL4o/e, LBL3o/e, LBL2o/e and LBL1o/e 3D metal lines in DL direction and are respectively connected to a 2D GBL1o/e metal line in the reverse side of Psub via three HV NMOS 3D transistors of 3DML and two sets of 3 connections of above 1)'s a and b.
Note, each GBL1o/e metal line is connected to each corresponding current-sensing input of each SA1o/e for performing the desired ABL program-verify or ABL read operation.
2) Each SA2o/e has one common input node of GBL2o/e shared by another 2 sets of similar control signals below:
   a. LG8, LG7 and ENDCR4o/e.
   b. LG6, LG5 and ENDCR3o/e.
The second plural drain nodes of all 3D strings of first four 3D ⅛-arrays formed in four respective LG8, LG7, LG6 and LG5 are respectively connected by LBL8o/e, LBL7o/e, LBL6o/e and LBL5o/e 3D metal lines in DL direction and are respectively connected to a 2D GBL2o/e metal in reverse side of Psub via three HV NMOS 3D transistors of 3DML and two sets of 3 connections of above 2)'s a and b on first ½ of total 3D NAND cells formed in the first set of four 3D ⅛-arrays.
Note, each GBL2o/e metal line is similarly connected to each corresponding current-sensing input of each SA2o/e for performing the desired ABL program-verify or ABL read operation on second ½ of total 3D NAND cells formed in the second set of four 3D ⅛-arrays.
   3) Likewise, another plural drain nodes of all strings of 3D-DCRs are connected by the same 3D metal lines referred as DCR1o/e in TIE1, DCR2o/e in TIE2, DCR3o/e in TIE3, and DCR4o/e in TIE4 in LBL or DL direction are also respectively connected to two separate common 2D metal nodes of GBL1o/e and GBL2o/e through four short 16 KB 2D DCR1o/e, 16 KB 2D DCR2o/e, 16 KB 2D DCR3o/e, and 16 KB 2D DCR4o/e metal lines to one corresponding 16 KB SAo/e voltage-sensing inputs via 16 KB 3D NMOS transistors of 3DMD.
Like FIG. 1 and FIG. 2, the size of each bit of PB in FIG. 3 is kept same comprising one identical circuit of nLC-latch circuit and one SA containing both current-sensing and voltage-sensing inputs as shown in FIG. 4 but with more inputs because each SA is shared by four 3D ⅛-arrays. Each SA's current-sensing input is used to perform ABL 16 KB nLC read in 1-cycle from one selected block's 16 KB 3D strings of four 3D ⅛-arrays. By contrast, each SA's voltage-sensing input is used to perform HBL 8 KB nLC page's digital data from of one 8 KB Odd/Even 3D-strings of same 3D-DCRs.
The size requirement of each 3D-DCR comprises at least 3×2n×16 KB DCR strings to allow the minimum storage of 3×2n×16 KB nLC digital page data for performing a desired 3-WL rotational nLC program scheme for this 3D hierarchical NAND array of the present invention. The reason for 3×2n×16 KB Cstrings are explained below.
1) For each ABL nLC program for each selected 3D WL, it requires n×16 KB program data to be stored locally in the 3D-DCRs.
2) For a HBL Recall operation, it requires 2n×8 KB 3D-DCRs' strings to store two separate n×8 KB Odd/Even program data to avoid DCRo/e-DCRo/e metal coupling effect.
3) For a 3-WL rotational ABL nLC program, it requires 3×2n×16 KB program data to be stored locally in the 3D-DCRs.

Note, the total size of 4 separate 3D DCRs in FIG. 3, each 3D DCR comprises double number of 3D Cstrings of each 3D DCRs' cstrings in FIG. 2 because the total number of concurrent ABL nLC program is kept the same of eight (8).

Similarly, FIG. 3 3D hierarchical array is formed with a similar (2D DL//3D LBL)_{⊥}(3D CSL//3D WL) scheme as FIG. 1 and FIG. 2 in accordance with the preferred concurrent operations of ABL nLC Program, ABL nLC Read, ABL nLC Program-verify, ABL nLC Erase-verify, HBL Recall, ABL write-back and nLC Erase of the present invention. Since only two 16 KB PBs are shared by eight ⅛-arrays, thus peripheral silicon area is further cut more than half over PBs sizes shown in FIG. 2 when a 3-WL rotational nLC program scheme is adopted for the 3D Hierarchical array concurrent operations. Thus the detailed explanations are omitted herein for description brevity.

Now the detailed operations of ABL program and Read of FIG. 2 are explained below.

Concurrent ABL nLC program: Up to 8-page 16 KB ABL nLC program can be concurrently performed as FIG. 1 and FIG. 2. Thus the detailed explanations are omitted herein for description brevity.
4) Concurrent ABL nLC Read or ABL nLC program-verify:
   Unlike FIG. 2 to perform 8-page ABL 16 KB read concurrently due to 8 PBs are available. But only 2-page concurrent ABL read can be performed in FIG. 3 due to only 2 PBs are available. But FIG. 3 does not slow down ABL read latency at all as compared to FIG. 2 as viewed from Off-chip Flash controller. The reason is because only one set of 16 KB DLs is shared by 2 distributed 16 KB PBs. The passage of each 16 KB nLC data from each corresponding ⅛-array to I/O can only be done 1-PB by 1-PB sequentially from four 16 KB PRB circuit (106). During the sequentially transferring four large 16 KB data from PRBs to I/Os, another four 16 KB data of next page of ABL read operation can be simultaneously performed in two separate 16 KB SAs current-sensing circuits. Once the first 2-page nLC data being sequentially and fully sent out to the Off-chip Flash controller, the next 2-page data from same four PBs can be transferred to same two 16 KB PRBs in parallel manner in 1-cycle to be ready for subsequent transferring to I/Os.
   5) Up to 8-page Concurrent nLC different operations:
   Any one or more than one of ⅛-array and its associated one 16 KB distributed LV PB can independently perform one of several key 3D NAND operations such as ABL nLC program, ABL nLC read, ABL nLC program-verify, erase, HBL erase-verify, or ABL 16 KB loading from 16 KB SCACHE, HBL Recall, ABL Write-Back complying with a strict rule no two operations using one common set of global 16 KB DLs, one common set of local 16 KB LBLs, one common set of 16 KB DCRs and common PBs at the same time during all different kinds of the preferred concurrent operations. The rest of detailed bias conditions and steps of each key concurrent operation are same, thus are same for both FIG. 1 and FIG. 2. thus are omitted herein for brevity.
FIG. 4 illustrates a schematic of a preferred 2D PB (Data Register 30) for all above preferred 3D hierarchical NAND arrays as shown in FIG. 1, FIG. 2 and FIG. 3 and all the likes. Each LV PB comprises one LV 2D TLC-latch circuit (86), one LV 2D SA circuit (104a) that can perform both ABL current-sensing in 1-cycle and HBL-DRAM voltage-sensing in 2 sequential cycles with optimal number of transistors, one PRE circuit (106) and one Match circuit (107) for performing ABL Program, ABL Program-verify or HBL Program-verify, ABL Read or HBL Read, HBL Recall, ABL Write-back, HBL Erase-verify, etc.

The detailed circuit explanations of each PB's circuit are summarized below.
1) Each bit of PB has one bidirectional input of a 2D GBL line which is shared by the following circuits.
   I. This is the 1^{st} option of each GBL to be directly connected to a bidirectional output node of 2D DL node via a 2D NMOS transistor of MD with its gate being tied to DLPBSW when other connections are biased in a tri-state as listed in iii below.
      i. When VDLPBSH≧Vdd+Vt, then VGBL=VDL.
      ii. When VDLPBSH=0V, then VGBL is disconnected from VDL.
      iii. VENPREB=VRW=VT1=VBIAS2=VBIAS1=0V.
   II. This is the 2^{nd} option of each GBL to be directly connected to an input of a current-sensing cascode-type SA that comprises one LV PMOS transistor MP1 in series with one NMOS transistor MN9 with its gate being tied to BIAS1 and other bias conditions are shown in iii below.
      i. MP1: Vsource=Vdd, Vdrain=VSA, and Vgate=REFV1.
      ii. MN9: Vsource=VGBL, Vdrain=VSA, and Vgate=BIAS1.
      iii. VBIAS2=VRW=VT1=VENPREB=0V: To disconnect PRE circuit, DL and the Voltage-sensing SA circuit of MN10 from each GBL so that only the Current-sensing ABL Read and Program-verify can be performed without being disturbed.
      iv. ABL Program-verify or Read operation: This is a cascade-type SA.
         When a programmed cell's Vt passes the Program-verify, there would be zero cell current flow or an extremely small cell current flow. Thus, VGBL=VBIAS1−Vt(MN9), thus VSA=Vdd.
         When a programmed cell's Vt fails the Program-verify, there would be some cell current flow. Thus, VGBL<VBIAS1−Vt(MN9), thus VSA<VBIAS1−Vt(MN9).
   III. This is the 3^{rd} option of each GBL to be directly connected to an input of a Voltage-sensing SA that comprises only one precharge NMOS transistor of MN10 with its gate being tied to BIAS12 and other bias conditions are shown in ii below.
      i. MN10: Vdrain=Vdd, Vsource=VGBL, and Vgate=VBIAS2.
      ii. VBIAS2=VRW=VT1=VENPREB=0V: To disconnect PRE circuit, DL and the Current-sensing SA circuit of MP1 and MN9 from each GBL so that only the Voltage-sensing HBL Read and HBL Program-verify can be performed without being disturbed.
   IV. This is the 4^{th} option of each GBL to be directly connected to one input Q1 of a DRAM-like Latch-type SA, which is comprised of the following devices.
      i. A latch-type circuit comprises MP3, MP2, MP4, MN2, MN4 and MN5.
      ii. One sensed voltage input of Q1 with a corresponding MN1 transistors with its gate being tied to T1, drain tied to GBL and source tied to Q1.
      iii. Two opposite reset signals of RS and LAT, where RS is connected to MN8's gate while LAT is connected to MN3's gate.
      iv. One Reference input to Q1B via MN7 with its gate being tied to T1 to track MN1 bias condition to achieve the highest level of reliable operation.
Note, this Voltage-sensing SA circuit is only used for HBL Read, HBL Program-verify and HBL Recall operations. The detailed steps of operation are omitted herein and can be referred to previous patents that were filed by the same inventor of the present invention.
FIG. 5 illustrates a detailed schematic of a preferred 2D TLC Latch circuit (86) of the present invention. This circuit is also disclosed in the previously filed patents by the same inventor of the present invention. The detailed operations are also omitted herein for the description simplicity of the present invention.

What is claimed is:

1. A 3D hierarchical NAND arrays comprising:
a plurality of divided 3D sub-arrays for nLC storage, a plurality of 3D N-bit Cstring-based DCRs with minimum memory capacity to store 3×2n pages of program data when a 3-WL rotational nLC program scheme is adopted, and a plurality of distributed N-bit PBs with same number of LBL lines;
each hierarchical 3D array comprises a plurality of 3D LGs and each LG comprises a plurality of 3D blocks connected by N local 3D LBL metal lines and 3D CSL lines and each block further comprises N strings without a need of extra local precharge line of LGps lines as disclosed in prior granted patents;
more number of distributed N-bit PBs would allow more powerful and flexible concurrent operations to be performed at the expense of taking larger silicon area in reversed side of Psub;
each bit of PB comprises one SA and one nLC-latch circuit. N-bit SA further comprises one N-bit Current-sensing circuit for performing ABL program, ABL page data loading in each N-bit CLBLs, ABL program-verify, ABL read on each 3D sub-array and ABL Write-back to each N-nit Cstring-based DCRs, and one N-bit Voltages-sensing circuit for performing HBL Recall from each page of selected Cstring-based N-bit DCR to N-bit PB;
the operations of the 3D hierarchical NAND and Cstring-based DCR arrays and their associated distributed PBs can be performed in both concurrent and pipeline manners, regardless of a 2-poly floating-gate 3D cell or a 1-poly charge-trapping 3D cell, regardless of GIDL or FN-tunneling erase scheme, regardless of SLC, MLC, TLC and XLC storage types.
